(19) United States
(12) Patent Application Publication
(10) Pub. No.: US 2026/0164743 A1
(43) Pub. Date: Jun. 11, 2026

(54) METHODS OF FABRICATING SEMICONDUCTOR DEVICE INCLUDING OXIDE SEMICONDUCTOR LAYER

(71) Applicant: SK hynix Inc., Gyeonggi-do (KR)

(72) Inventor: Seung Wook RYU, Gyeonggi-do (KR)

(21) Appl. No.: 19/201,933

(22) Filed: May 8, 2025

(30) Foreign Application Priority Data
Dec. 10, 2024 (KR) 10-2024-0183142

(51) Int. Cl. H01L 21/443; H10B 12/00; H10D 30/63; H10D 62/17; H10D 62/80; H10D 64/62

(52) U.S. Cl. CPC H10D 64/011; H10B 12/05; H10D 30/63; H10D 62/292; H10D 62/875; H10D 64/62; H10B 12/315

(57) ABSTRACT

A method of fabricating a semiconductor device including an oxide semiconductor layer. A first conductive layer is formed over a substrate, and a conductive protecting layer covering the first conductive layer is formed by a reaction of a first metal precursor and a reducing gas. An oxide semiconductor layer is formed to extend substantially vertically from the conductive protecting layer, and a second conductive layer is formed on a first side surface of the oxide semiconductor layer.

### CROSS-REFERENCE TO RELATED APPLICATIONS

The present application claims priority under 35 U.S.C § 119(a) to Korean Application No. 10-2024-0183142, filed on Dec. 10, 2024, the entire contents of which are incorporated herein by reference.

### BACKGROUND

### 1. Technical Field

Embodiments of the present disclosure generally relate to a semiconductor device, and more particularly, to methods of fabricating a semiconductor device including an oxide semiconductor layer.

### 2. Related Art

As semiconductor devices become more highly integrated, attempts are being made to apply vertical transistors with a vertical channel structure to the semiconductor devices. Attempts are being made to implement transistors that apply oxide semiconductor layers as vertical channels.

### SUMMARY

A method of fabricating a semiconductor device according to an embodiment of the present disclosure may include forming a first conductive layer over a substrate, forming a conductive protecting layer covering the first conductive layer by a reaction of a first metal precursor and a reducing gas, forming an oxide semiconductor layer extending substantially vertically from the conductive protecting layer, and forming a second conductive layer positioned on a first side surface of the oxide semiconductor layer.

A method of fabricating a semiconductor device according to an embodiment of the present disclosure may include forming a first conductive layer over a substrate, forming an oxide semiconductor layer extending substantially vertically from the first conductive layer, and forming a second conductive layer positioned on a first side surface of the oxide semiconductor layer by a reaction of a metal precursor and an oxidizing gas.

A method of fabricating a semiconductor device according to an embodiment of the present disclosure may include forming a first conductive layer over a substrate, forming a conductive protecting layer that covers the first conductive layer and comprises an indium nitride (InN) layer, forming an oxide semiconductor layer extending substantially vertically from the conductive protecting layer, and forming a second conductive layer positioned on a first side surface of the oxide semiconductor layer.

### BRIEF DESCRIPTION OF THE DRAWINGS

FIG. 1 is a schematic view illustrating a semiconductor device according to an embodiment of the present disclosure.

FIG. 2 through FIG. 7 are schematic views illustrating a method of fabricating a semiconductor device according to an embodiment of the present disclosure.

FIG. 8 is a schematic view illustrating a semiconductor device according to an embodiment of the present disclosure.

FIG. 9 through FIG. 17 are schematic views illustrating a method of fabricating a semiconductor device according to an embodiment of the present disclosure.

FIG. 18 is a schematic cross-sectional view illustrating a method of fabricating a semiconductor device according to an embodiment of the present disclosure.

FIG. 19 is a schematic cross-sectional view illustrating a method of fabricating a semiconductor device according to an embodiment of the present disclosure.

### DETAILED DESCRIPTION

The cross-hatching throughout the figures illustrates corresponding or similar areas between the figures rather than indicating the materials associated with the areas.

The terms used herein may correspond to words selected in consideration of their functions in presented embodiments, and the meanings of the terms may be construed to be different according to ordinary skill in the art to which the embodiments belong. The meaning of the terms used is in accordance with the defined definition if specifically defined herein, and in the absence of a specific definition, may be interpreted as meaning generally recognized by those skilled in the art.

Terms such as “first” and “second” are used to distinguish between various elements and do not imply size, order, priority, quantity, or importance of the elements. For example, a first element may be named as a second element in one example, and the second element may be named as a first element in another example. When one component is identified as “connected” to another component, the components may be connected directly or through an intervening component between the components. When two components are identified as “directly connected,” one component is directly connected to the other component without an intervening component between the two components. In the present disclosure, terms such as “first,” “second,” “third,” etc. are used to distinguish components, and are not used to limit the components themselves or to imply a specific order. In the present disclosure, terms such as “front side,” “back side,” etc., do not limit a specific direction, location, or component. Terms such as “below,” “beneath,” “lower,” “above,” “upper,” etc., can be used to describe the spatial relative location between components.

Throughout the specification, the same reference numerals may refer to the same components. The same reference numerals or similar reference numerals may be described with reference to other drawings, even if they are not mentioned or described in the drawings. Also, even if the reference numerals are not indicated, they may be described with reference to other drawings.

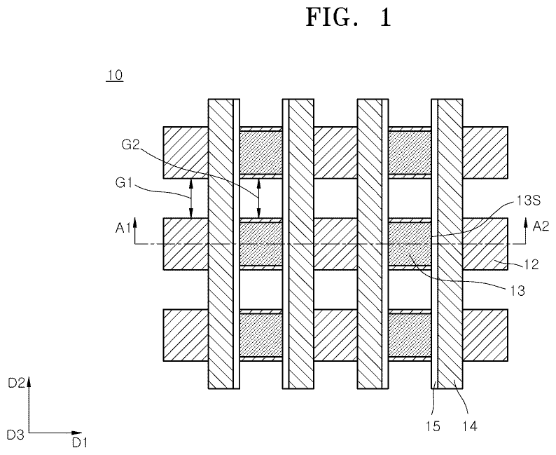

FIG. 1 is a schematic plan view illustrating a semiconductor device 10 according to an embodiment of the present disclosure. FIG. 1 illustrates the semiconductor device 10 implemented through a method of fabricating the semiconductor device according to an embodiment. FIG. 1 illustrates a shape in which elements constituting the semiconductor device 10 are disposed on a plane. The method of fabricating the semiconductor device according to an embodiment is not limited to the semiconductor device 10 of FIG. 1.

Referring to FIG. 1, the semiconductor device 10 includes first conductive lines 12, an oxide semiconductor layer 13, and second conductive lines 14. The first conductive lines 12 include bit lines, and the second conductive lines 14 include word lines. Each of the second conductive lines 14 may be a gate of a transistor connected to the word line.

The first conductive lines 12 extend along a first direction D1. A plurality of first conductive lines 12 are disposed spaced apart from each other in a second direction D2. Spaces G1 between neighboring first conductive lines 12 are filled with an insulating material which electrically isolates the first conductive lines 12 from each other. Each of the second conductive lines 14 extends along the second direction D2. The first conductive lines 12 and the second conductive lines 14 extend to intersect each other while being spaced apart from each other in a third direction D3. The third direction D3 is perpendicular to the first direction D1 and the second direction D2. The first direction D1, the second direction D2, and the third direction D3 indicate X-axis, Y-axis, and Z-axis in the X-Y-Z coordinate system, respectively, in this embodiment, but the embodiments of the present disclosure are not limited to this. For example, in an embodiment, (not shown) the second direction D2 may be a diagonal direction with respect to the first direction D1.

The oxide semiconductor layer 13 is connected to the first conductive lines 12 and extends substantially vertically from the first conductive lines 12, thereby providing vertical channels of vertical transistors. The vertical channels are formed in the oxide semiconductor layer 13 by controlling a voltage applied to the first conductive lines 12 and the second conductive lines 14. The oxide semiconductor layer 13 includes a metal-oxide semiconductor material. The oxide semiconductor layer 13 is positioned to overlap with the first conductive lines 12. Each of patterns of the oxide semiconductor layer 13 has a fin shape or a pillar shape. The patterns of the oxide semiconductor layer 13 having such a shape are disposed spaced apart from each other in the first direction D1 and the second direction D2. The fin shape or the pillar shape is an example of the patterned oxide semiconductor layer 13, and the shape of the patterned oxide semiconductor layer 13 is not limited to the fin shape or the pillar shape. Spaces G2 between neighboring patterns of the oxide semiconductor layers 13 in the second direction D2 are filled with an insulating layer to electrically isolate the patterns of the oxide semiconductor layer 13 from each other.

The second conductive lines 14 are positioned on a first side surface 13S of the oxide semiconductor layer 13. Two second conductive lines 14 extend side by side with the oxide semiconductor layer 13 therebetween. A dielectric layer 15 isolating the oxide semiconductor layer 13 and the second conductive lines 14 is positioned between the first side 13S of the oxide semiconductor layer 13 and the second conductive lines 14. The dielectric layer 15 may be a gate dielectric layer made of a dielectric material.

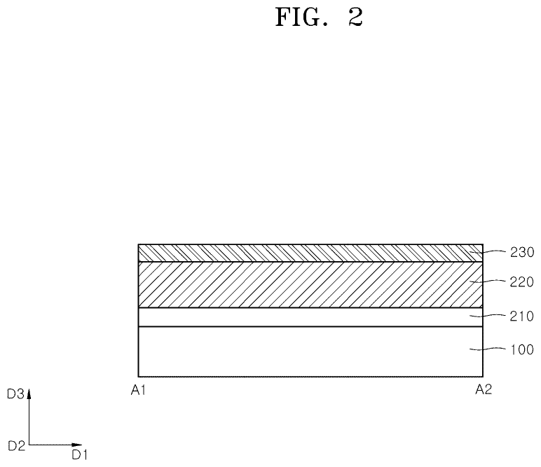

FIG. 2 through FIG. 7 are schematic cross-sectional views illustrating a method of fabricating a semiconductor device according to an embodiment of the present disclosure. FIG. 2 through FIG. 7 illustrate cross-sectional shapes of the semiconductor device in FIG. 1 taken along a direction in which the first conductive lines 12 extend. FIG. 2 through FIG. 7 illustrate the cross-sectional shapes of the semiconductor device in FIG. 1 taken along line A1-A2.

Referring to FIG. 2, a first conductive layer 220 is formed over a substrate 100. The substrate 100 is a base on which a semiconductor fabricating process is performed. The substrate 100 includes a semiconductor substrate. The substrate 100 includes a semiconductor material such as silicon (Si). In some embodiments, the substrate 100 includes silicon germanium (SiGe) or silicon carbide (SiC). In some embodiments, the substrate 100 includes a compound semiconductor material such as gallium arsenide (GaAs).

A buffer layer 210 is disposed between the substrate 100 and the first conductive layer 220. The buffer layer 210 is formed before forming the first conductive layer 220 over the substrate 100. The buffer layer 210 is formed to cover the top surface of the substrate 100. The buffer layer 210 includes an insulating material. The buffer layer 210 is formed as a layer that electrically isolates the first conductive layer 220 from the substrate 100. The buffer layer 210 includes silicon oxide, silicon nitride, or a combination thereof.

In some embodiments, the first conductive layer 220 includes a metal layer. The metal layer may include a metal such as tungsten (W). The first conductive layer 220 is formed on the buffer layer 210. In some embodiments, an adhesive layer (not shown) may be further formed under the first conductive layer 220. The adhesive layer when used may further improve adhesion between the first conductive layer 220, e.g., a tungsten (W) layer and an underlying layer such as the buffer layer 210. For example, the adhesive layer may include titanium nitride (TiN). In some embodiments, a titanium nitride (TiN) layer may be formed on the first conductive layer 220 (e.g., a tungsten (W) layer) as an upper layer that protects the first conductive layer 220 (e.g., the tungsten (W) layer). In some embodiments, the first conductive layer 220 (e.g., the tungsten (W) layer) has a thickness of tens Å through hundreds Å, however the embodiments are not limited to this. In some embodiments, the first conductive layer 220, (e.g., the tungsten (W) layer) is formed in a thickness of 100 Å through 400 Å. In some embodiments, the titanium nitride (TiN) layer is formed in a thickness of tens Å, but the embodiments are not limited to this. The titanium nitride (TiN) layer may be formed in a thickness of 10 Å through 50 Å.

In some embodiments, the first conductive layer 220 is formed in a composite layer of TiN/W or a composite layer of TiN/W/TiN in this example, however the embodiments are not limited to this. The first conductive layer 220 may include a metal other than tungsten (W), and a metal nitride other than titanium nitride (TiN), or a metal silicide. In some embodiments, the first conductive layer 220 may include a ruthenium (Ru) layer. The first conductive layer 220 is formed using various deposition processes. For example, the first conductive layer 220 is formed by a deposition process such as an atomic layer deposition (ALD), a physical vapor deposition (PVD), or a chemical vapor deposition (CVD).

In some embodiments, a conductive protecting layer 230 is formed on the first conductive layer 220 substantially covering the entire upper (top) surface of the first conductive layer 220. The conductive protecting layer 230 functions to reduce or suppress deterioration of the first conductive layer 220 which is positioned underneath. The conductive protecting layer 230 is formed using a deposition process excluding an oxidizing reactant, such as an oxidizing gas. In some embodiments, the deposition process includes atomic layer deposition (ALD), physical vapor deposition (PVD), or chemical vapor deposition (CVD). The oxidizing gas includes, for example, ozone (O₃), water vapor (H₂O), or oxygen gas (O2) that induces an oxidizing reaction. In some embodiments, the conductive protecting layer 230 is formed by a deposition process using a reducing reactant, such as reducing gas. The reducing gas includes, for example, ammonia gas (NH₃) or hydrogen gas (H₂) that induces a reducing reaction.

Forming the conductive protecting layer 230 by a deposition process including a reducing reaction substantially suppresses penetration of the oxidizing gas or the oxidizing reactant into the underlying first conductive layer 220 during the forming of the conductive protecting layer 230. Accordingly, during formation of the conductive protecting layer 230, it is possible to substantially suppress oxidation of the first conductive layer 220 and deterioration of the electrical characteristics, such as conductivity, of the first conductive layer 220.

The conductive protecting layer 230 acts as an oxidizing reactant penetration-inhibiting layer that inhibits or reduces movement of the oxidizing reactant such as oxygen, oxygen ions, ozone, and water vapor to the underlaying first conductive layer 220 in subsequent processes. The conductive protecting layer 230 acts as an oxygen-trapping layer that traps oxygen or an oxidizing reactant that penetrates into the conductive protecting layer 230 from the outside. The conductive protecting layer 230 is formed of a conductive material that reacts with oxygen or an oxidizing reactant penetrating into the conductive protecting layer 230 from the outside to generate conductive oxide.

The conductive protecting layer 230 is formed by a reaction of a first metal precursor and a reducing gas. In an embodiment, the first metal precursor includes a first ruthenium (Ru) precursor. The first ruthenium (Ru) precursor may be a ruthenium compound in which ruthenium (Ru) is bonded to a ligand capable of undergoing a reducing reaction with ammonia gas or hydrogen gas. The first ruthenium (Ru) precursor is a ruthenium (Ru) compound including a carbonyl group. The first ruthenium (Ru) precursor includes ruthenium tricarbonyl cyclohexadiene (Ru(CO)₃(CHD)) or ruthenium di-t-butylacetamidinate dicarbonyl (Ru(tBu-Me-amd)₂(CO)₂). In some embodiments, the first ruthenium (Ru) precursor includes ruthenium tetraoxide (RuO₄). For example, in some embodiments, the conductive protecting layer 230 includes a ruthenium (Ru) layer formed by a reaction of the first ruthenium (Ru) precursor and a reducing gas.

In an embodiment, the first metal precursor includes an indium (In) precursor. The indium (In) precursor may be an indium (In) compound in which indium (In) is bonded to a ligand capable of undergoing a reduction reaction with ammonia gas or hydrogen gas. The indium (In) compound includes indium trichloride (InCl₃). In some embodiments, the conductive protecting layer 230 includes an indium nitride (InN) layer formed by a reaction of the indium (In) precursor and a reducing gas.

After forming the conductive protecting layer 230 on the first conductive layer 220, a patterning process is performed to separate a double layer including the first conductive layer 220 and the conductive protecting layer 230 into the first conductive lines 12 in FIG. 1. Some portions of the double layer including the first conductive layer 220 and the conductive protecting layer 230 are selectively removed, and an insulating layer is formed to fill the spaces where the portions are removed. The patterning process and a process of forming the insulating layer are performed immediately after forming the conductive protecting layer 230 in this embodiment, but the embodiments are not limited to this.

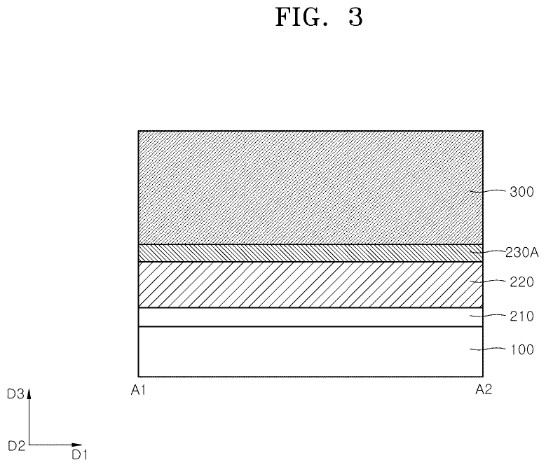

Referring to FIG. 2 and FIG. 3, an oxide semiconductor layer 300 is formed on the conductive protecting layer 230 in FIG. 2. The oxide semiconductor layer 300 includes a metal-oxide semiconductor material such as indium gallium zinc oxide (IGZO). In some embodiments, the metal-oxide semiconductor material may be zinc oxide (IZTO) or zinc tin oxide (ZTO). The oxide semiconductor layer 300 is formed to have a concentration profile in which upper and lower portions of the oxide semiconductor layer 300 have a relatively higher concentration of indium (In) than a middle portion, and the middle portion has a relatively higher concentration of oxygen than the upper or lower portion. The oxide semiconductor layer 300 is formed such that the concentration of indium (In) is higher than the concentration of zinc (Zn) or tin (Sn). The oxide semiconductor layer 300 is formed in a thickness of several hundred Å to several thousand Å. For example, the oxide semiconductor layer 300 is formed in a thickness of 200 Å through 1,000 Å, however, the embodiments are not limited to this.

The oxide semiconductor layer 300 is formed to cover an upper surface of the conductive protecting layer 230 in FIG. 2 while contacting the surface of the conductive protecting layer. When the oxide semiconductor layer 300 is deposited, oxygen or an oxidizing reactant may penetrate from the oxide semiconductor layer 300 into the conductive protecting layer 230. As the oxygen, oxygen gas, or the oxidizing reactant penetrates into the conductive protecting layer 230, the oxygen, the oxygen gas, or the oxidizing reactant reacts with a conductive material in the conductive protecting layer 230 to generate a conductive oxide material within the conductive protecting layer 230. The oxygen, the oxygen gas, or the oxidizing reactant penetrated into the conductive protecting layer 230 may oxidize the conductive protecting layer 230. In this way, by oxidation of the conductive protecting layer 230, the conductive protecting layer 230 is converted into a conductive protecting layer 230A that includes conductive oxide.

As the conductive protecting layer is oxidized, the oxygen or the oxidizing reactant penetrating into the conductive protecting layer 230A is trapped by the conductive protecting layer 230A. Accordingly, transfer of the oxygen, the oxygen gas, or the oxidizing reactant to the first conductive layer 220 under the conductive protecting layer 230A can be suppressed or reduced. In this way, oxidation of the first conductive layer 220 can be suppressed, and thus, resistance of the first conductive layer 220 may be suppressed from being decreased.

The oxide material generated when the conductive protecting layer 230A is oxidized may have conductivity. Accordingly, even though the conductive protecting layer 230A is oxidized, an increase in electrical resistance between the oxide semiconductor layer 300 and the first conductive layer 220 can be suppressed. The increase in contact resistance between the oxidized conductive protecting layer 230A and the oxide semiconductor layer 300 may be suppressed.

In an embodiment, the conductive protecting layer 230 in FIG. 2 includes a ruthenium (Ru) layer formed by a reaction of the first ruthenium (Ru) precursor and a reducing gas. The oxygen or oxygen gas penetrating the ruthenium (Ru) layer reacts with at least some of the ruthenium (Ru) to generate a conductive oxide material, such as ruthenium dioxide (RuO₂), within the ruthenium (Ru) layer. The ruthenium (Ru) layer may be oxidized into a conductive oxide layer such as ruthenium dioxide (RuO₂) layer by an oxidation reaction. Because the oxidized conductive protecting layer 230A includes ruthenium dioxide (RuO₂), the increase in the resistance of the conductive protecting layer 230A may be suppressed.

In an embodiment, the conductive protecting layer 230 in FIG. 2 includes an indium nitride (InN) layer. The oxygen or oxygen gas penetrating the indium nitride (InN) layer reacts with the indium nitride (InN) to generate a conductive oxide material, such as indium trioxide (In₂O₃), within the indium nitride (InN) layer. By the oxidation reaction, the indium nitride (InN) layer is oxidized into a conductive oxide layer such as indium trioxide (In₂O₃). Because the oxidized conductive protecting layer 230A includes indium trioxide (In₂O₃), an increase in the resistance of the conductive protecting layer 230A maybe suppressed.

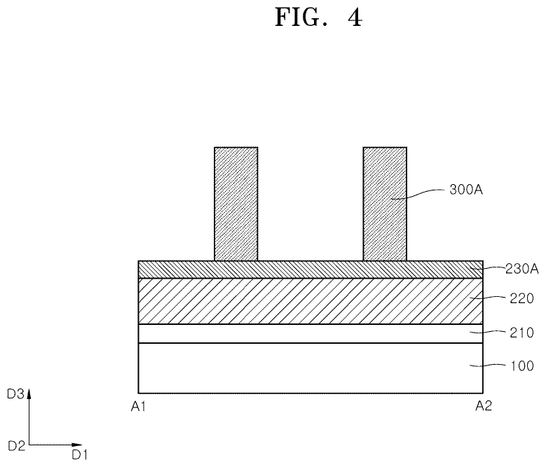

Referring to FIG. 3 and FIG. 4, some portions of the oxide semiconductor layer 300 in FIG. 3 are removed to separate the oxide semiconductor layer 300 into patterns 300A of the oxide semiconductor layer. The patterns 300A of the oxide semiconductor layer may be referred to as oxide semiconductor layers for convenience of description. Each of the patterns 300A of the oxide semiconductor layer has a shape protruding in the third direction D3 from the conductive protecting layer 230A. The patterns 300A of the oxide semiconductor layer are separated into a plurality of fin shapes or pillar shapes. The pattern 300A of the oxide semiconductor layer has a shape in which a lower portion is connected to the conductive protecting layer 230A and extends substantially vertically from the conductive protecting layer 230A. The pattern 300A of the oxide semiconductor layer is formed as an element that provides a vertical channel of a vertical transistor. By selectively removing some portions of the oxide semiconductor layer 300 in FIG. 3, some surface portions of the conductive protecting layer 230A are exposed around the patterns 300A of the oxide semiconductor layer.

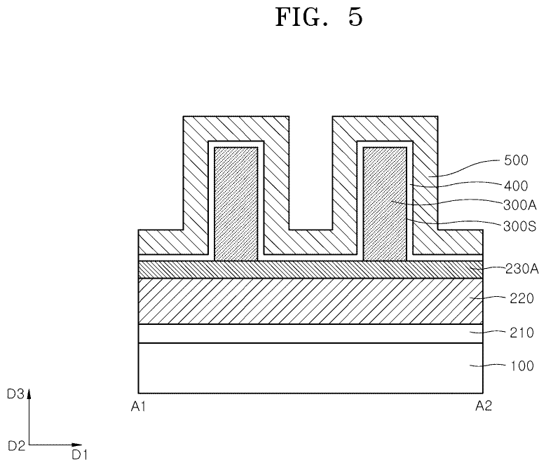

Referring to FIG. 5, a dielectric layer 400 is formed to cover the patterns 300A of the oxide semiconductor layer. The dielectric layer 400 also is formed to cover the portions of the conductive protecting layer 230A, exposed by the patterns 300A of the oxide semiconductor layer. The dielectric layer 400 may be formed as a gate dielectric layer of the vertical transistor. In some embodiments, the dielectric layer 400 includes silicon oxide. For example, the dielectric layer 400 includes silicon oxide, silicon nitride, silicon oxynitride, a high-k material, or a combination thereof.

A second conductive layer 500 is formed on the dielectric layer 400. The second conductive layer 500 is deposited such that some portions of the second conductive layer 500 are positioned on first side surfaces 300S of the patterns 300A of the oxide semiconductor layer. The second conductive layer 500 is formed by a deposition process using an oxidizing gas or an oxidizing reactant. A reducing gas or a reducing reactant is excluded from the deposition process for the second conductive layer 500.

The second conductive layer 500 is formed by a reaction of a second metal precursor and an oxidizing gas. The second metal precursor includes a ruthenium compound, such as bis(ethylcyclopentadienyl)ruthenium(II) (Ru(EtCp)₂), ruthenocene (Bis(cyclopentadienyl)ruthenium (RuCP₂), or bis(2,4-dimethylpentadienyl) ruthenium (Ru(DMPD)₂. The oxidizing gas or the oxidizing reactant includes ozone (O₃), water vapor (H₂O), or oxygen gas (O₂).

By depositing the second conductive layer 500 using an oxidizing gas or an oxidizing reactant, oxygen is additionally injected into the underlying dielectric layer 400 and patterns 300A of the oxide semiconductor layer. As the oxygen penetrates into the dielectric layer 400 and the patterns 300A of the oxide semiconductor layer, the dielectric layer 400 and the patterns 300A of the oxide semiconductor layer can be cured. Because the second conductive layer 500 is deposited while excluding a reducing gas or a reducing reactant, it is possible to reduce or suppress damage caused by reduction of oxide forming the dielectric layer 400 and the patterns 300A of the oxide semiconductor layer by the reducing gas or the reducing reactant. Accordingly, deterioration of the channels of the vertical transistors can be suppressed.

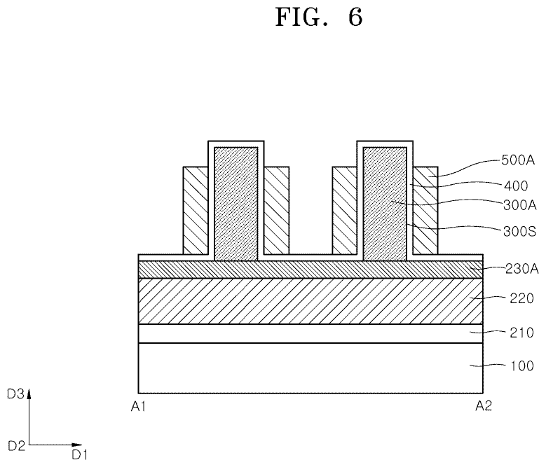

Referring to FIG. 5 and FIG. 6, patterns 500A of the second conductive layer are separated from the second conductive layer 500. Specifically, some portions of the second conductive layer 500 are selectively removed to separate the second conductive layer 500 into the patterns 500A of the second conductive layer which are positioned on the first side surfaces 300S of the patterns 300A of the oxide semiconductor layer. The patterns 500A of the second conductive layer may be referred to as the second conductive layer for convenience of description. The second conductive layer 500 is anisotropically etched to expose some portions of the dielectric layer 400. Accordingly, the patterns 500A of the second conductive layer may remain only on the first side surfaces 300S of the patterns 300A of the oxide semiconductor layer.

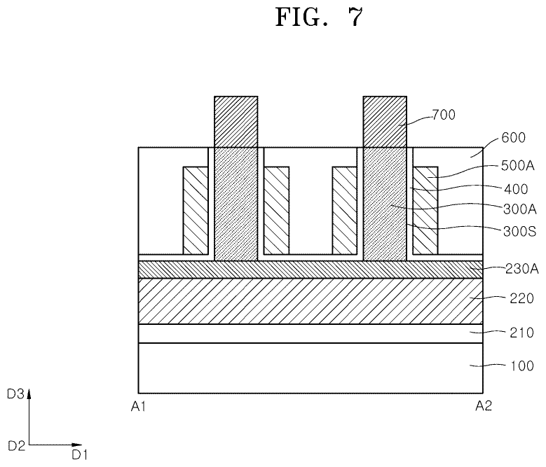

Referring to FIG. 7, capacitors 700 are formed. The capacitors are formed on the patterns 300A of the oxide semiconductor layer and are electrically connected to the patterns 300A of the oxide semiconductor layer. For example, an insulating layer 600 is formed to cover the exposed portions of the patterns 500A of the second conductive layer and the dielectric layer 400. A portion of the insulating layer 600 and a portion of the dielectric layer 400 are removed to expose the portions of the patterns 300A of the oxide semiconductor layer. Thus, capacitors 700 are formed which are connected to the exposed portions of the patterns 300A of the oxide semiconductor layer. Accordingly, a semiconductor device including the capacitors connected to vertical transistor structures are implemented. Each of the vertical transistor structures includes the first conductive layer 220 as a bit line, the pattern 500A of the second conductive layer as a word line crossing the bit line, and the pattern 300A of the oxide semiconductor layer in which a channel perpendicular to the bit line is formed.

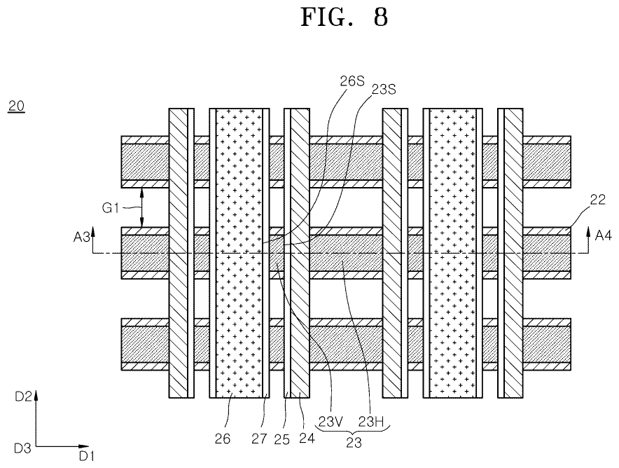

FIG. 8 is a schematic plan view illustrating a semiconductor device 20 according to an embodiment of the present disclosure. FIG. 8 illustrates the semiconductor device 20 implemented by a method of fabricating a semiconductor device according to an embodiment of the present disclosure. FIG. 8 illustrates a shape in which elements constituting the semiconductor device 20 are arranged on a plane. However, it is noted that the method of fabricating the semiconductor device according to an embodiment is not limited to the semiconductor device 20 in FIG. 8.

Referring to FIG. 8, the semiconductor device 20 includes first conductive lines 22, an oxide semiconductor layer 23, second conductive lines 24, and third conductive lines 26. The first conductive lines 22 include bit lines, the second conductive lines 24 include first word lines, and the third conductive lines 26 include second word lines. The second conductive lines 24 may be first gates of transistors connected to the first word lines, and the third conductive lines 26 may be second gates of the transistors connected to the second word lines.

The first conductive lines 22 extend in a first direction D1. A plurality of first conductive lines 22 are disposed spaced apart from each other in a second direction D2. Spaces G1 between neighboring first conductive lines 22 are filled with an insulating layer electrically isolating the first conductive lines 22 from each other. The second and third conductive lines 24 and 26 extend in the second direction D2. The first and second conductive lines 22 and 24 extend to intersect each other while being spaced apart from each other in a third direction D3. The first and third conductive lines 22 and 26 extend to intersect each other while being spaced apart from each other in the third direction D3.

The oxide semiconductor layer 23 is connected to the first conductive lines 22. The oxide semiconductor layer 23 extends substantially vertically from the first conductive lines 22 to provide vertical channels of the vertical transistors. The oxide semiconductor layer 23 is formed in patterns including vertical extension portions 23V of the oxide semiconductor layer and horizontal connection portions 23H of the oxide semiconductor layer. The vertical extension portions 23V of the oxide semiconductor layer are portions of the oxide semiconductor layer 23 which have a shape extending vertically from the first conductive lines 22 or a shape extending in the third direction D3. The horizontal connection portions 23H of the oxide semiconductor layer are other portions of the oxide semiconductor layer 23 which connect the vertical extension portions 23V of a pair of neighboring oxide semiconductor layers to each other. The second conductive lines 24 are positioned on side surfaces of the vertical extension portions 23V of the oxide semiconductor layer which are first side surfaces 23S of the oxide semiconductor layer 23. The vertical extension portions 23V of the oxide semiconductor layer are positioned on second side surfaces 26S of the third conductive lines 26. The vertical extension portions 23V of the oxide semiconductor layer are positioned between the second conductive lines 24 and the third conductive lines 26.

The vertical extension portions 23V of the oxide semiconductor layer are portions in which the vertical channels of the vertical transistors are formed. By voltages applied to the first conductive lines 22 and the second conductive lines 24, the vertical channels of the vertical transistors may be formed in the vertical extension portions 23V of the oxide semiconductor layer. A back bias may be applied to the vertical extension portions 23V of the oxide semiconductor layer by the voltage applied to the third conductive lines 26.

The oxide semiconductor layer 23 overlaps with some portions of the first conductive lines 22. A plurality of patterns of the oxide semiconductor layer 23 are spaced apart from each other in the second direction D2 in which the second conductive lines 24 extend. The plurality of patterns of the oxide semiconductor layer 23 are spaced apart from each other by the third conductive lines 26. The horizontal connection portions 23H of the oxide semiconductor layer may extend to pass below the second conductive lines 24 and are connected to the vertical extension portions 23V of the oxide semiconductor layer.

A first dielectric layer 25 is disposed as a first gate dielectric layer between the second conductive lines 24 and the vertical extension portions 23V of the oxide semiconductor layer. A second dielectric layer 27 is disposed as a second gate dielectric layer between the third conductive lines 26 and the vertical extension portions 23V of the oxide semiconductor layer.

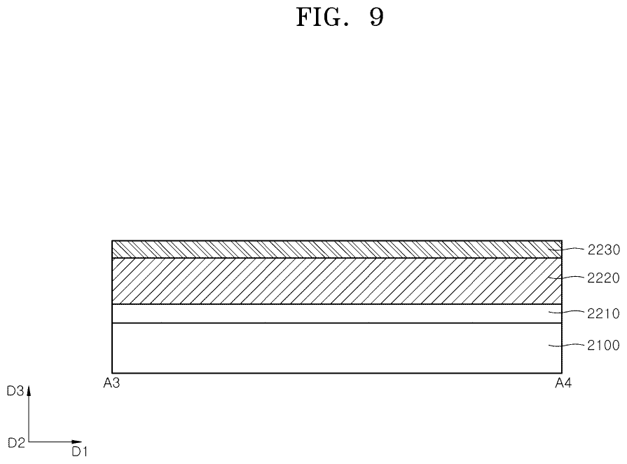

FIG. 9 through FIG. 17 are schematic cross-sectional views illustrating a method of fabricating a semiconductor device according to an embodiment of the present disclosure. FIG. 9 through FIG. 17 illustrate cross-sectional shapes of the semiconductor device taken along a direction in which the first conductive lines 22 in FIG. 8 extend. FIG. 9 through FIG. 17 illustrate the cross-sectional shapes of the semiconductor device taken along line A3-A4 in FIG. 8.

Referring to FIG. 9, a first conductive layer 2220 is formed over a substrate 2100. A buffer layer 2210 is formed between the substrate 2100 and the first conductive layer 2220. The buffer layer 2210 is formed as a layer that electrically isolates the substrate 2100 and the first conductive layer 2220 from each other. The first conductive layer 2220 is formed on the buffer layer 2210 after the buffer layer 2210 is formed on the substrate 2100. The first conductive layer 2220 includes a metal layer such as, for example, a tungsten (W) layer. In some embodiments, as an example, the first conductive layer 2220 is formed as a composite layer of TiN/W or TiN/W/TiN, but the embodiments are not limited to this. The first conductive layer 2220 may include a ruthenium (Ru) layer.

A conductive protecting layer 2230 is formed on the first conductive layer 2220. The conductive protecting layer 2230 is formed to substantially cover the entire upper surface of the first conductive layer 2220. The conductive protecting layer 2230 is designed to reduce or suppress deterioration of the first conductive layer 2220 which is positioned thereunder. The conductive protecting layer 2230 is formed by a deposition process using a reducing reactant such as a reducing gas. The reducing gas includes ammonia gas (NH₃) or hydrogen gas (H₂).

The conductive protecting layer 2230 may act as an oxidizing reactant penetration-inhibiting layer that inhibits or reduces movement of an oxidizing reactant such as oxygen, oxygen ions, ozone, and water vapor to the underlying first conductive layer 2220 in subsequent processes. The conductive protecting layer 2230 may act as an oxygen-trapping layer that traps oxygen or the oxidizing reactant penetrating into the conductive protecting layer 2230 from the outside. The conductive protecting layer 2230 is formed of a conductive material that can react with the oxygen or the oxidizing reactant penetrating into the conductive protecting layer 2230 from the outside to generate conductive oxide.

The conductive protecting layer 2230 is formed by a reaction of a first metal precursor and a reducing gas. In an embodiment, the first metal precursor includes a first ruthenium (Ru) precursor. The conductive protecting layer 2230 includes a ruthenium (Ru) layer formed by a reaction of the first ruthenium (Ru) precursor and the reducing gas. In an embodiment, the conductive protecting layer 2230 includes an indium nitride (InN) layer formed by a reaction of an indium (Ru) precursor and the reducing gas.

After forming the conductive protecting layer 2230 on the first conductive layer 2220, a patterning process is performed to separate a double layer including the first conductive layer 2220 and the conductive protecting layer 2230 into the first conductive lines 22 shown in FIG. 8, however, the embodiments of the present disclosure are not limited to this.

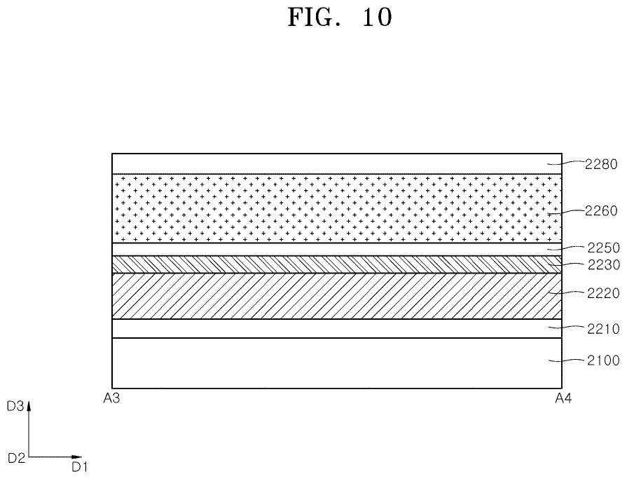

Referring to FIG. 10, a first insulating layer 2250 is formed on the conductive protecting layer 2230. The first insulating layer 2250 includes an insulating material such as silicon oxide (SiO₂), silicon nitride (SiN), or silicon carbide (SiCO). A third conductive layer 2260 is formed on the first insulating layer 2250. The first insulating layer 2250 functions to electrically isolate the third conductive layer 2260 from the first conductive layer 2220 or the conductive protecting layer 2230. The third conductive layer 2260 may be a layer to be patterned as the third conductive lines 26 in FIG. 8. The third conductive layer 2260 includes a metal layer such as a titanium nitride (TiN) layer. The titanium nitride (TiN) layer is formed in a thickness of several hundred Å. The titanium nitride (TiN) layer is formed in a thickness of approximately 700 Å in this embodiment, but the embodiments of the present disclosure are not limited to this. A second insulating layer 2280 is formed on the third conductive layer 2260. The second insulating layer 2280 is formed as a protecting layer or a hard mask layer that covers and protects the third conductive layer 2260. The second insulating layer 2280 includes a silicon oxide layer, a silicon nitride layer, or a composite layer thereof.

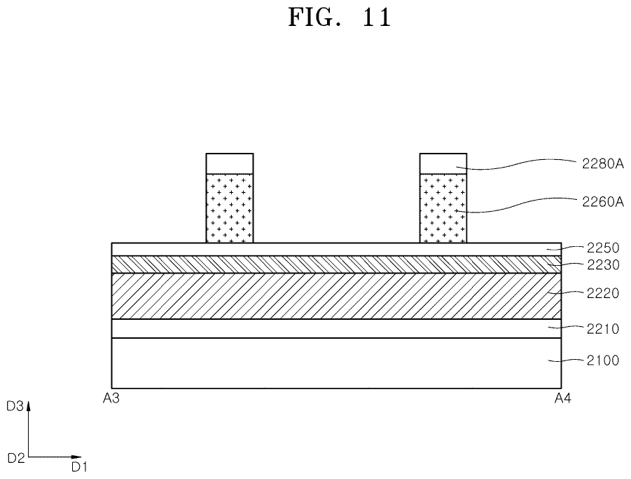

Referring to FIG. 10 and FIG. 11, some portions of the second insulating layer 2280 and some portions of the third conductive layer 2260 are removed to separate the second insulating layer 2280 and the third conductive layer 2260 into patterns 2280A of the second insulating layer and patterns 2260A of the third conductive layer. The patterns 2280A of the second insulating layer and the patterns 2260A of the third conductive layer may also be referred to as the second insulating layer and the third conductive layer, respectively, for convenience of description. Some portions of the second insulating layer 2280 and the third conductive layer 2260 are removed by a selective etching process. As some portions of the second insulating layer 2280 and some portions of the third conductive layer 2260 are removed, some portions of the first insulating layer 2250 are exposed by the patterns 2280A of the second insulating layer and the patterns 2260A of the third conductive layer.

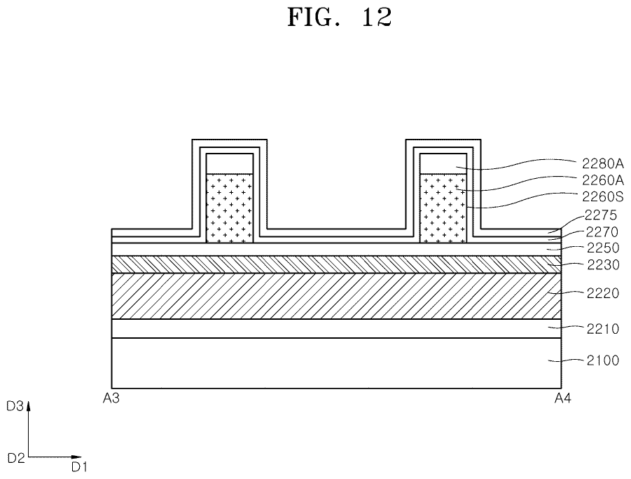

Referring to FIG. 12, a second dielectric layer 2270 is formed that covers the patterns 2280A of the second insulating layer and the patterns 2260A of the third conductive layer. The second dielectric layer 2270 also extends to cover the exposed portions of the first insulating layer 2250. The second dielectric layer 2270 includes silicon oxide. The second dielectric layer 2270 is formed as a second gate dielectric layer that contacts the patterns 2260A of the third conductive layer. A sacrificial layer 2275 that covers the second dielectric layer 2270 is further formed. The sacrificial layer 2275 may be a layer that protects the second dielectric layer 2270 in a subsequent process and is subsequently removed. The sacrificial layer 2275 includes, for example, polycrystalline silicon.

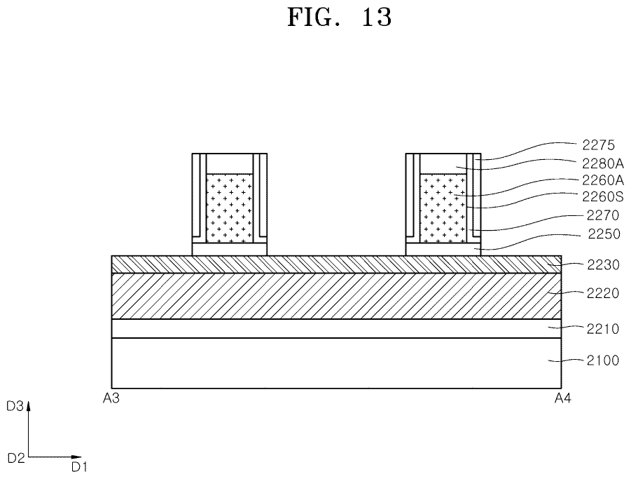

Referring to FIG. 13, some portions of the sacrificial layer 2275, some portions of the second dielectric layer 2270, and some portions of the first insulating layer 2250 are removed to expose some portions of the underlying conductive protecting layer 2230. Anisotropic etching is performed on a resulting structure in which the sacrificial layer 2275, the second dielectric layer 2270, and the first insulating layer 2250 are formed to sequentially remove some portions of the sacrificial layer 2275, some portions of the second dielectric layer 2270, and some portions of the first insulating layer 2250. While the patterns 2280A of the second insulating layer serve as a hard mask or an etching mask, the patterns 2260A of the third conductive layer are maintained. As some portions of the second dielectric layer 2270 are removed, other portions of the second dielectric layer 2270 remain in the form of spacers on second side surfaces 2260S of the patterns 2260A of the third conductive layer. Each of the remaining portions of the second dielectric layer 2270 may be formed as a second gate dielectric layer that covers the second side surface 2260S of the patterns 2260A of the third conductive layer. The remaining portions of the first insulating layer 2250 overlap with the patterns 2260A of the third conductive layer. The remaining portions of the first insulating layer 2250 electrically insulate and isolate the patterns 2260A of the third conductive layer from the first conductive layer 2220 and the conductive protecting layer 2230. Thereafter, the remaining sacrificial layer 2275 is removed.

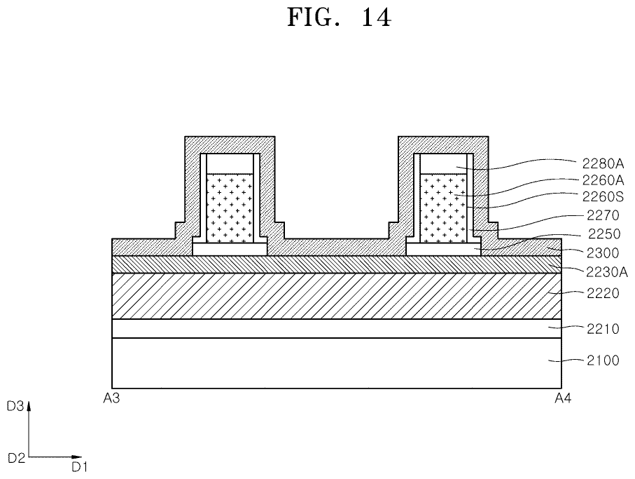

Referring to FIG. 13 and FIG. 14, an oxide semiconductor layer 2300 is formed to cover the portions of the conductive protecting layer 2230 in FIG. 13, which are exposed by removing some portions of the first insulating layer 2250. The oxide semiconductor layer 2300 is formed to extend substantially vertically in a third direction D3 from the conductive protecting layer 2230. The oxide semiconductor layer 2300 is formed to conformally cover the remaining second dielectric layer 2270 and patterns 2280A of the second insulating layer.

The oxide semiconductor layer 2300 includes a metal-oxide semiconductor material such as indium gallium zinc oxide (IGZO). Some portions of the oxide semiconductor layer 2300 are in contact with an exposed surface of the conductive protecting layer 2230 and cover the exposed surface of the conductive protecting layer 2230. While the oxide semiconductor layer 2300 is deposited, oxygen or an oxidizing reactant may penetrate from the oxide semiconductor layer 2300 into the conductive protecting layer 2230. The oxygen, oxygen gas, or oxidizing reactant penetrates into the conductive protecting layer 2230 and reacts with the conductive material that forms this layer to generate conductive oxide within the conductive protecting layer 2230. Thus, the penetrated oxygen, oxygen gas, or oxidizing reactant oxidizes the conductive protecting layer 2230. In this way, by oxidation of the conductive protecting layer 2230, the conductive protecting layer 2230 is converted into the conductive protecting layer 2230A which includes conductive oxide.

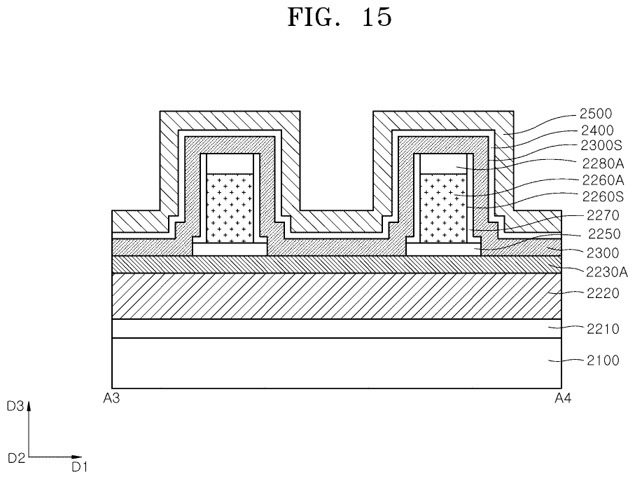

Referring to FIG. 15, a first dielectric layer 2400 is formed. The first dielectric layer 2400 is covering the oxide semiconductor layer 2300. The first dielectric layer 2400 may be formed as a first gate dielectric layer of a vertical transistor. The first dielectric layer 2400 includes oxide, silicon nitride, silicon oxynitride, a high-k material, or a combination thereof.

A second conductive layer 2500 is then formed on the first dielectric layer 2400. The second conductive layer 2500 is formed by a deposition process such that some portions of the second conductive layer 2500 are positioned on vertical first side surfaces 2300S of the oxide semiconductor layer 2300. The second conductive layer 2500 is formed by a deposition process using an oxidizing gas or an oxidizing reactant. A reducing gas and a reducing reactant are excluded from the process of depositing the second conductive layer 2500.

The second conductive layer 2500 is formed by a reaction of a second metal precursor and an oxidizing gas. The second metal precursor includes a second ruthenium (Ru) precursor. The oxidizing gas or the oxidizing reactant includes ozone (O₃), water vapor (H₂O), or oxygen gas (O₂). By depositing the second conductive layer 2500 using the oxidizing gas or the oxidizing reactant, oxygen is additionally injected into the underlying first dielectric layer 2400 and oxide semiconductor layer 2300. As oxygen penetrates into the first dielectric layer 2400 and the oxide semiconductor layer 2300, it contributes to curing these layers. The curing process enhances the chemical and structural stability of these layers which is important for their performance characteristics. Because the second conductive layer 2500 is deposited while excluding the reducing gas or the reducing reactant, damage caused by reduction of oxides forming the first dielectric layer 2400 and the oxide semiconductor layer 2300 by the reducing gas or the reducing reactant can be reduced or suppressed. Accordingly, deterioration of a channel of a vertical transistor can be suppressed. This method minimizes or fully suppresses damage to these layers and helps preserve the integrity of the vertical transistor's channel. This ensures better performance and longevity of the transistor by suppressing issues that could arise from oxide reduction and associated deterioration.

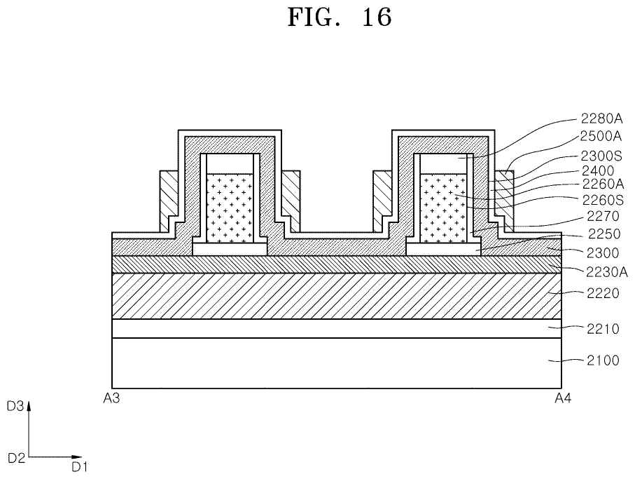

Referring to FIG. 15 and FIG. 16, the second conductive layer 2500 is separated into patterns 2500A of the second conductive layer. Some portions of the second conductive layer 2500 are selectively removed to separate the second conductive layer 2500 into the patterns 2500A of the second conductive layer, positioned on the first side surfaces 2300S of the oxide semiconductor layer 2300. The patterns 2500A of the second conductive layer may be referred to as the second conductive layer for convenience of description. By anisotropically etching the second conductive layer 2500 to expose some portions of the first dielectric layer 2400, the patterns 2500A of the second conductive layer may remain only on the first side surfaces 2300S of the oxide semiconductor layer 2300.

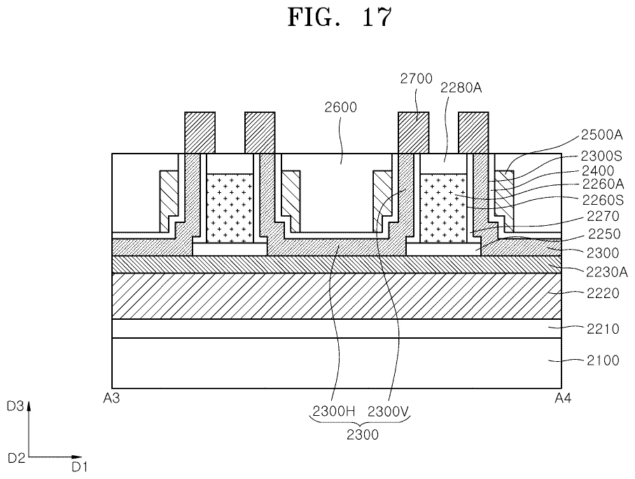

Referring to FIG. 17, capacitors 2700 electrically connected to the oxide semiconductor layer 2300 are formed on the oxide semiconductor layer 2300. Specifically, a third insulating layer 2600 is formed to cover the patterns 2500A of the second conductive layer and the exposed portions of the first dielectric layer 2400, and some portions of the third insulating layer 2600 and some portions of the first dielectric layer 2400 are removed to expose some portions of the oxide semiconductor layer 2300. When portions of the exposed oxide semiconductor layer 2300 are removed, the patterns 2280A of the second insulating layer underneath are exposed. Hence, this removal process effectively removes the exposed portions of the oxide semiconductor layer 2300 and divides the oxide semiconductor layer 2300 into a plurality of distinct patterns which include vertical extension portions 2300V and horizontal connection portions 2300H. Because vertical channels are formed in the vertical extension portions 2300V of the oxide semiconductor layer, the capacitors 2700 are formed to be electrically connected to the vertical extension portions 2300V of the oxide semiconductor layer. This configuration ensures that the capacitors 2700 are integrated into the design while maintaining the necessary electrical links for proper device functionality.

Accordingly, a semiconductor device including a capacitor connected to the vertical transistor structure can be implemented. The vertical transistor structure includes the first conductive layer 2220 as a bit line, the pattern 2500A of the second conductive layer as a first word line intersecting the bit line, the pattern 2260A of the third conductive layer as a second word line opposite to the first word line, and the vertical extension portion 2300V of the oxide semiconductor layer in which a channel perpendicular to the bit line is formed.

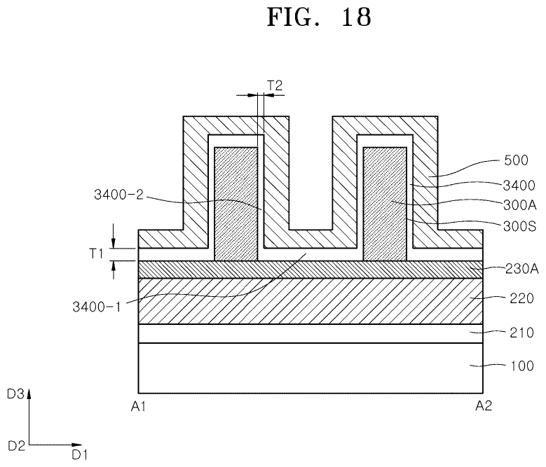

FIG. 18 is a schematic cross-sectional view illustrating a method of fabricating a semiconductor device according to an embodiment of the present disclosure. FIG. 18 is a schematic cross-sectional view illustrating a cross-sectional structure in which a first dielectric layer 3400 that covers patterns 300A of an oxide semiconductor layer and a second conductive layer 500 are formed in the method of fabricating the semiconductor device according to an embodiment of the present disclosure. In FIG. 18, the same reference numerals as in FIG. 2 through FIG. 7 indicate the same elements.

Referring to FIG. 18, the first dielectric layer 3400 is formed that covers the patterns 300A of the oxide semiconductor layer and extends to cover portions of a conductive protecting layer 230A exposed by the patterns 300A of the oxide semiconductor layer. The second conductive layer 500 is formed on the first dielectric layer 3400. The first dielectric layer 3400 may be formed as a gate dielectric layer of a vertical transistor.

The first dielectric layer 3400 is formed to have a partially different thickness by controlling a deposition process. The first dielectric layer 3400 includes first portions 3400-1 of the first dielectric layer and second portions 3400-2 of the first dielectric layer having different thicknesses. The first portions 3400-1 of the first dielectric layer are portions covering the conductive protecting layer 230A, and the second portions 3400-2 of the first dielectric layer are portions covering the first side surfaces 300S of the patterns 300A of the oxide semiconductor layer.

A thickness T1 of the first portion 3400-1 of the first dielectric layer is thicker than a thickness T2 of the second portion 3400-2 of the first dielectric layer. By making the thickness T1 of the first portion 3400-1 of the first dielectric layer thicker than the thickness T2 of the second portion 3400-2 of the first dielectric layer, the parasitic capacitance of a metal-insulator-metal (MIM) capacitor including the second conductive layer 500, the first portion 3400-1 of the dielectric layer, and the conductive protecting layer 230A can be reduced. In addition, by making the thickness T1 of the first portion 3400-1 of the first dielectric layer thicker than the thickness T2 of the second portion 3400-2 of the first dielectric layer, electrical breakdown that may occur due to the thin first portion 3400-1 of the first dielectric layer can be suppressed.

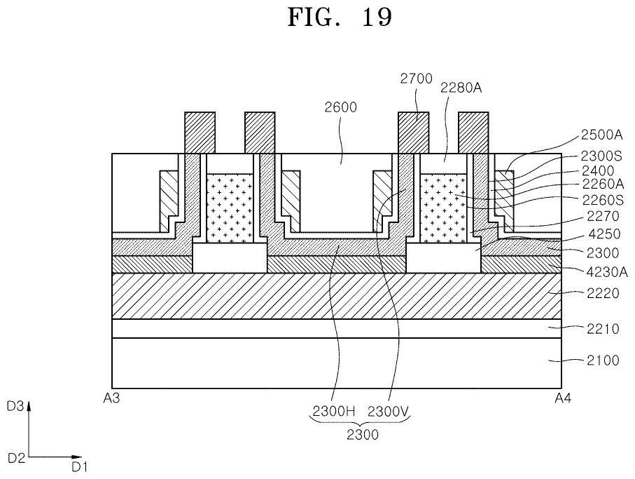

FIG. 19 is a schematic cross-sectional view illustrating a method of fabricating a semiconductor device according to an embodiment of the present disclosure. FIG. 19 is a schematic cross-sectional view illustrating a cross-sectional structure including a conductive protecting layer 4230A formed in the method of fabricating the semiconductor device according to an embodiment. In FIG. 19, the same reference numerals as in FIG. 9 through FIG. 17 may indicate the same elements.

Referring to FIG. 19, the conductive protecting layer 4230A is formed to be positioned between horizontal connection portions 2300H of an oxide semiconductor layer 2300 and a first conductive layer 2220. The conductive protecting layer 4230A is formed to overlap vertically with the horizontal connection portions 2300H of the oxide semiconductor layer 2300. The conductive protecting layer 4230A is restricted not to overlap with a first insulating layer 4250. In an embodiment, as shown in FIG. 9, a conductive protecting layer 2230 is formed to cover a first conductive layer 2220, and some portions of the conductive protecting layer 2230 are selectively removed to form the conductive protecting layer 4230A in a pattern shape of FIG. 19. Accordingly, the first insulating layer 4250 is formed to separate the pattern shapes of the conductive protecting layer 4230A.

The technical concepts of the present disclosure are presented in conjunction with various examples and embodiments. Those skilled in the art will recognize that various modifications, additions, and substitutions are possible without departing from the scope and technical concepts of the present disclosure. The embodiments disclosed in the present specification should be considered from an illustrative standpoint and not considered a restrictive standpoint. The scope of the present disclosure is not limited to the descriptions, and all distinctive features within an equivalent scope should be construed as included in the present disclosure. Any change within the meaning and range of equivalency of the claims are included within their scope. Furthermore, the embodiments may be combined to form additional embodiments.

What is claimed is:

1. A method of fabricating a semiconductor device, the method comprising:
forming a first conductive layer over a substrate;
forming a conductive protecting layer covering the first conductive layer by a reaction of a first metal precursor and a reducing gas;
forming an oxide semiconductor layer extending substantially vertically from the conductive protecting layer; and
forming a second conductive layer positioned on a first side surface of the oxide semiconductor layer.

2. The method of claim 1,
wherein the first conductive layer comprises a bit line;
wherein the second conductive layer comprises a word line intersecting the bit line; and
wherein the oxide semiconductor layer provides a channel substantially perpendicular to the bit line.

3. The method of claim 1, wherein the conductive protecting layer comprises a ruthenium (Ru) layer or an indium nitride (InN) layer.

4. The method of claim 1,
wherein the first metal precursor comprises a first ruthenium (Ru) precursor; and
wherein the reducing gas comprises at least one selected from the group consisting of ammonia gas (NH₃) and hydrogen gas (H₂).

5. The method of claim 4, wherein the first ruthenium (Ru) precursor comprises at least one selected from the group consisting of ruthenium tricarbonyl cyclohexadiene (Ru(CO)₃(CHD)), ruthenium di-t-butylacetamidinate dicarbonyl (Ru(tBu-Me-amd)₂(CO)₂), and ruthenium tetraoxide (RuO₄).

6. The method of claim 1, wherein the second conductive layer is formed by a reaction of a second metal precursor and an oxidizing gas.

7. The method of claim 6,
wherein the second metal precursor comprises a second ruthenium (Ru) precursor; and
wherein the oxidizing gas comprises at least one selected from the group consisting of ozone (O3), water vapor (H2O), and oxygen gas (O2).

8. The method of claim 7, wherein the second ruthenium (Ru) precursor comprises at least one selected from the group consisting of bis(ethylcyclopentadienyl)ruthenium(II) (Ru(EtCp)₂, ruthenocene (Bis(cyclopentadienyl)ruthenium (RuCP₂), and bis(2,4-dimethylpentadienyl) ruthenium (Ru(DMPD)₂.

9. The method of claim 1, wherein the oxide semiconductor layer comprises indium gallium zinc oxide (IGZO), indium tin zinc oxide (IZTO), or zinc tin oxide (ZTO).

10. The method of claim 1, wherein the oxide semiconductor layer has a fin shape or a pillar shape.

11. The method of claim 1,
further comprising forming a first dielectric layer that comprises a first portion of the first dielectric layer covering the conductive protecting layer and a second portion of the first dielectric layer extending from the first portion of the first dielectric layer to cover the first side surface of the oxide semiconductor layer,
wherein the first portion of the first dielectric layer is thicker than the second portion of the first dielectric layer.

12. The method of claim 1,
further comprising:
forming a third conductive layer extending perpendicularly to the conductive protecting layer while being separated from the conductive protecting layer by an insulating layer; and
forming a second dielectric layer covering a second side surface of the third conductive layer,
wherein the oxide semiconductor layer extends to cover the second dielectric layer.

13. The method of claim 12,
wherein the first conductive layer comprises a bit line;
wherein the second conductive layer comprises a first word line intersecting the bit line;
wherein the oxide semiconductor layer provides a channel perpendicular to the bit line; and
wherein the third conductive layer comprises a second word line positioned on an opposite side of the first word line with the oxide semiconductor layer interposed therebetween.

14. A method of fabricating a semiconductor device, the method comprising:
forming a first conductive layer over a substrate;
forming an oxide semiconductor layer extending substantially vertically from the first conductive layer; and
forming a second conductive layer positioned on a first side surface of the oxide semiconductor layer by a reaction of a metal precursor and an oxidizing gas.

15. The method of claim 14,
wherein the first conductive layer comprises a bit line;
wherein the second conductive layer comprises a word line intersecting the bit line; and
wherein the oxide semiconductor layer provides a channel substantially perpendicular to the bit line.

16. The method of claim 14,
wherein the metal precursor comprises a ruthenium (Ru) precursor; and
wherein the oxidizing gas comprises at least one selected from the group consisting of ozone (O₃), water vapor (H₂O), and oxygen gas (O₂).

17. The method of claim 16, wherein the ruthenium (Ru) precursor comprises at least one selected from the group consisting of bis(ethylcyclopentadienyl)ruthenium(II) (Ru(EtCp)₂, ruthenocene (Bis(cyclopentadienyl)ruthenium (RuCP₂), and bis(2,4-dimethylpentadienyl) ruthenium (Ru(DMPD)₂.

18. The method of claim 14, wherein the oxide semiconductor layer has a fin shape or a pillar shape.

19. The method of claim 14,
further comprising forming a first dielectric layer that comprises a first portion of the first dielectric layer covering the conductive protecting layer and a second portion of the first dielectric layer extending from the first portion of the first dielectric layer to cover the first side surface of the oxide semiconductor layer,
wherein the first portion of the first dielectric layer is thicker than the second portion of the first dielectric layer.

20. A method of fabricating a semiconductor device, the method comprising:
forming a first conductive layer over a substrate;
forming a conductive protecting layer that covers the first conductive layer and comprises an indium nitride (InN) layer;
forming an oxide semiconductor layer extending substantially vertically from the conductive protecting layer; and
forming a second conductive layer positioned on a first side surface of the oxide semiconductor layer.
